(19) United States
(12) Patent Application Publication
(10) Pub. No.: US 2014/0175423 A1
(43) Pub. Date: Jun. 26, 2014

(54) THIN FILM TRANSISTOR ARRAY PANEL AND METHOD OF MANUFACTURING THE SAME

(71) Applicant: Samsung Display Co., Ltd., Yongin-City (KR)

(72) Inventors: Chang-Oh JEONG, Suwon-si (KR); Kyung Seop KIM, Hwaseong-si (KR); Hong Long NING, Suwon-si (KR); Byeong-Beom KIM, Asan-si (KR); Joon Yong PARK, Gunpo-si (KR); Jin Ho HWANG, Osan-si (KR); Dong Min LEE, Anyang-si (KR)

(73) Assignee: Samsung Display Co., Ltd., Yongin-City (KR)

(21) Appl. No.: 13/896,045

(22) Filed: May 16, 2013

(30) Foreign Application Priority Data
Dec. 21, 2012 (KR) 10-2012-0151130

(51) Int. Cl. H01L 27/12

(52) U.S. Cl. CPC H01L 27/1218; H01L 27/1259
USPC 257/43; 438/34

(57) ABSTRACT

A thin film transistor array panel is provided. The thin film transistor array panel includes a substrate, a seed layer positioned on the substrate, and a semiconductor layer positioned on the seed layer, wherein a lattice mismatch between the seed layer and the semiconductor layer is equal to or less than 1.4%.

### CROSS-REFERENCE TO RELATED APPLICATION

This application claims priority to and the benefit of Korean Patent Application No. 10-2012-0151130 filed in the Korean Intellectual Property Office on Dec, 21, 2012, the entire contents of which are incorporated herein by reference.

### BACKGROUND

(a) Technical Field

The present disclosure relates to a thin film transistor array panel and a method of manufacturing the same.

(b) Description of the Related Art

In general, a flat panel display (such as a liquid crystal display or an organic light emitting device) includes a plurality of pairs of field generating electrodes, and electro-optical active layers interposed therebetween. In a liquid crystal display, the electro-optical active layer includes a liquid crystal layer. In an organic light emitting device, the electro-optical active layer includes an organic emission layer. A pair of field generating electrodes is typically connected to a switching element to receive an electrical signal, and the electro-optical active layer converts the electrical signal into an optical signal to display an image.

The flat panel display includes a thin film transistor (TFT) which is used as the switching element. The flat panel display also includes signal lines (such as gate lines) that transmit scanning signals for controlling the thin film transistor, and data lines that transmit signals to be applied to pixel electrodes.

The characteristic of the thin film transistor is determined by the type of semiconductor material used in the transistor. Amorphous silicon is often used as the semiconductor material in the transistor. However, the performance of the thin film transistor is limited by the low charge mobility in amorphous silicon. Although polycrystalline silicon (polysilicon) can be used to produce a high performance thin film transistor having high charge mobility, the high cost and low uniformity of polysilicon can limit the production of large-scale thin film transistor array panels.

To overcome the above limitations in amorphous silicon and polysilicon, an oxide semiconductor having characteristics superior to those of amorphous silicon and polysilicon has been proposed. For example, the oxide semiconductor may have higher electron mobility and higher on/off current ratio than amorphous silicon, and lower cost and higher uniformity than polysilicon.

However, including the oxide semiconductor in the thin film transistor can create other problems. For example, the characteristics of the thin film transistor may deteriorate due to lattice mismatch between the oxide semiconductor and other layers in the thin film transistor. Additionally, the characteristics of the oxide semiconductor layer may deteriorate when by-products (such as gases) from the semiconductor processing enter the channel region of the thin film transistor and react with the oxide semiconductor layer.

### SUMMARY

The present disclosure is directed to address at least the above problems relating to lattice mismatch and transistor performance in a thin film transistor array panel.

According to some embodiments of the present inventive concept, a thin film transistor array panel is provided. The thin film transistor array panel includes a substrate, a seed layer positioned on the substrate, and a semiconductor layer positioned on the seed layer, wherein a lattice mismatch between the seed layer and the semiconductor layer is equal to or less than about 1.4%.

In some embodiments, the seed layer may include an amorphous oxide semiconductor, and the semiconductor layer may include a crystalline oxide semiconductor.

In some embodiments, the seed layer may include an oxide semiconductor including at least one of indium, gallium, and zinc.

In some embodiments, the semiconductor layer may include an oxide semiconductor including at least one of indium, gallium, zinc, and tin.

In some embodiments, the oxide semiconductor may be formed having a C-axis aligned crystal (CAAC) structure.

In some embodiments, the thin film transistor array panel may further include a gate electrode positioned on the substrate, a gate insulating layer positioned on the substrate to cover the gate electrode, and a source electrode and a drain electrode positioned on the semiconductor layer, wherein the seed layer and the semiconductor layer may be sequentially positioned on the gate insulating layer.

In some embodiments, the thin film transistor array panel may further include a barrier layer positioned on the semiconductor layer, and an edge portion of the barrier layer may be covered by the source electrode and the drain electrode.

In some embodiments, the barrier layer may be formed having an island shape.

In some embodiments, the barrier layer may include aluminum oxide.

According to some other embodiments of the present inventive concept, a method of manufacturing a thin film transistor array panel is provided. The method includes forming a gate electrode on a substrate, forming a gate insulating layer on the substrate to cover the gate electrode, forming a seed material layer on the gate insulating layer, forming a semiconductor material layer on the seed material layer, forming a first photosensitive film pattern on the semiconductor material layer, forming a semiconductor layer and a seed layer by patterning the semiconductor material layer and the seed material layer using the first photosensitive film pattern as a first etch mask, removing the first photosensitive film pattern, forming a data wiring material layer on the gate insulating layer to cover the semiconductor layer, forming a second photosensitive film pattern on the data wiring material layer, and forming a source electrode and a drain electrode facing the source electrode, by patterning the data wiring material layer using the second photosensitive film pattern as a second etch mask.

In some embodiments, a lattice mismatch between the seed layer and the semiconductor layer may be equal to or less than about 1.4%.

In some embodiments, the seed layer may be formed of an amorphous oxide semiconductor, and the semiconductor layer may be formed of a crystalline oxide semiconductor.

In some embodiments, the seed layer may be formed of an oxide semiconductor including at least one of indium, gallium, and zinc, and the semiconductor layer may be formed of an oxide semiconductor including at least one of indium, gallium, zinc, and tin.

In some embodiments, the oxide semiconductor may be formed having a C-axis aligned crystal (CAAC) structure.

In some embodiments, the method of manufacturing the thin film transistor array panel may further include forming a barrier material layer on the semiconductor material layer before forming the first photosensitive film pattern, wherein the barrier material layer is formed of aluminum oxide, and forming a barrier layer by patterning the barrier material layer using the first etch mask.

In some embodiments, the method of manufacturing the thin film transistor array panel may further include exposing an edge portion of the barrier layer by ash processing the first photosensitive film pattern after forming the semiconductor layer and the seed layer, and etching the barrier layer using the ash-processed first photosensitive film pattern as a third etch mask, wherein the data wiring material layer is formed covering an edge portion of the semiconductor layer, the edge portion being exposed by etching the barrier layer.

In some embodiments, the method of manufacturing the thin film transistor array panel may further include forming a passivation layer on the source electrode and the drain electrode, and forming a pixel electrode on the passivation layer, wherein the pixel electrode and the drain electrode are connected through a contact hole formed at the passivation layer.

In some embodiments, the method of manufacturing the thin film transistor array panel may further include performing a heat treatment of the seed material layer.

### BRIEF DESCRIPTION OF THE DRAWINGS

FIG. 1 is a top plan view illustrating a thin film transistor array panel according to an exemplary embodiment of the present inventive concept.

FIG. 2 is a cross-sectional view taken along line II-II of FIG. 1.

FIG. 3A is a diagram illustrating the extent of a lattice mismatch between an oxide semiconductor layer and a neighboring layer in a conventional thin film structure.

FIG. 3B is a diagram illustrating the extent of a lattice mismatch between an oxide semiconductor layer and a neighboring layer according to an exemplary embodiment of the present inventive concept.

FIGS. 4 to 15 are cross-sectional views illustrating an exemplary method of manufacturing the thin film transistor array panel of FIGS. 1 and 2.

FIG. 16 is a cross-sectional view illustrating a thin film transistor array panel according to another exemplary embodiment of the present inventive concept.

FIGS. 17 to 23 are cross-sectional views illustrating an exemplary method of manufacturing the thin film transistor array panel of FIG. 16.

FIG. 24 is a cross-sectional view illustrating a thin film transistor array panel according to a further exemplary embodiment of the present inventive concept.

### DETAILED DESCRIPTION OF THE EMBODIMENTS

Hereinafter, exemplary embodiments of the present inventive concept will be described in detail with reference to the accompanying drawings. As those skilled in the art would realize, the described embodiments may be modified in various ways without departing from the spirit or scope of the present disclosure.

In the drawings, the thickness of the layers, films, panels, regions, etc., may be exaggerated for clarity. It will be understood that when a layer is referred to as being “on” another layer or substrate, the layer can be directly formed on the other layer or substrate, or formed with intervening elements or layers present. Like reference numerals designate like elements throughout the specification.

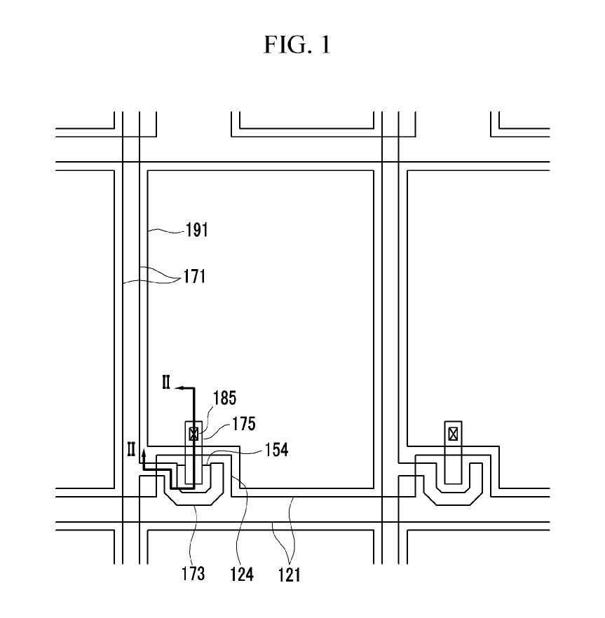

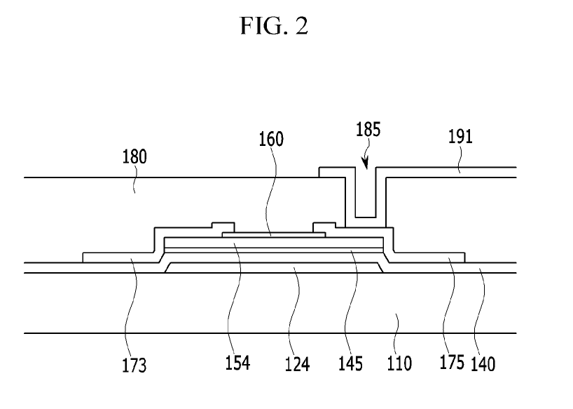

FIG. 1 is a top plan view illustrating a thin film transistor array panel according to an exemplary embodiment of the present inventive concept. FIG. 2 is a cross-sectional view taken along line II-II of FIG. 1.

Referring to FIGS. 1 and 2, a plurality of gate lines 121 for transmitting gate signals are formed extending in a horizontal direction on a substrate 110. Each gate line 121 includes a gate electrode 124 formed protruding from the gate line 121.

The gate line 121 and gate electrode 124 may be formed of metals or metal-based compounds including aluminum-based metals (such as aluminum (Al) or aluminum alloys), silver-based metals (such as silver (Ag) or silver alloys), copper-based metals (such as copper (Cu) or copper alloys), molybdenum-based metals (such as molybdenum (Mo) or molybdenum alloys), chromium (Cr), titanium (Ti), tantalum (Ta), or manganese (Mn).

In some embodiments, the gate line 121 and gate electrode 124 may be formed from a single layer. In some other embodiments, the gate line 121 and gate electrode 124 may be formed of multiple layers (such as double layers or triple layers) by combining layers having different physical properties.

A gate insulating layer 140 is formed on the gate line 121 (and gate electrode 124). The gate insulating layer 140 may include silicon oxide, silicon nitride, silicon oxynitride, aluminum oxide, or other similar insulating materials. In some embodiments, the gate insulating layer 140 may have a multilayer structure including two or more different insulating layers (not illustrated). For example, in those embodiments, an upper layer portion of the gate insulating layer 140 may be formed of silicon oxide or aluminum oxide, and a lower layer portion of the gate insulating layer 140 may be formed of silicon nitride. Alternatively, the upper layer portion of the gate insulating layer 140 may be formed of silicon oxide or aluminum oxide, and the lower layer portion of the gate insulating layer 140 may be formed of silicon oxynitride. The inclusion of an oxide in the gate insulating layer 140 (in contact with an oxide semiconductor layer 154) can help to mitigate deterioration of a channel layer.

As shown in FIG. 2, a seed layer 145 is formed on the gate insulating layer 140. The seed layer 145 includes an oxide semiconductor. For example, the seed layer 145 may be formed of an amorphous oxide semiconductor, and may include at least one of the elements indium, gallium, and zinc. In some embodiments, the seed layer 145 may have a thickness equal to or more than approximately 10 Å. In some embodiments, the seed layer 145 may have a thickness equal to or less than approximately 300 Å. In some embodiments, the seed layer 145 may have a lattice structure.

As shown in FIG. 2, a semiconductor layer 154 is formed on the seed layer 145. In some embodiments, the semiconductor layer 154 includes an oxide semiconductor. For example, the semiconductor layer 154 may be formed of a crystalline oxide semiconductor, and may include at least one of the elements indium, gallium, zinc, and tin. In some embodiments, the semiconductor layer 154 is formed having a thickness greater than that of the seed layer 145. In some embodiments, the semiconductor layer 154 may be formed having a C-axis aligned crystal (CAAC) structure. The CAAC structure is a hexagonal structure when seen from a C-axis direction, and is a layered structure when seen from a direction perpendicular to the C-axis.

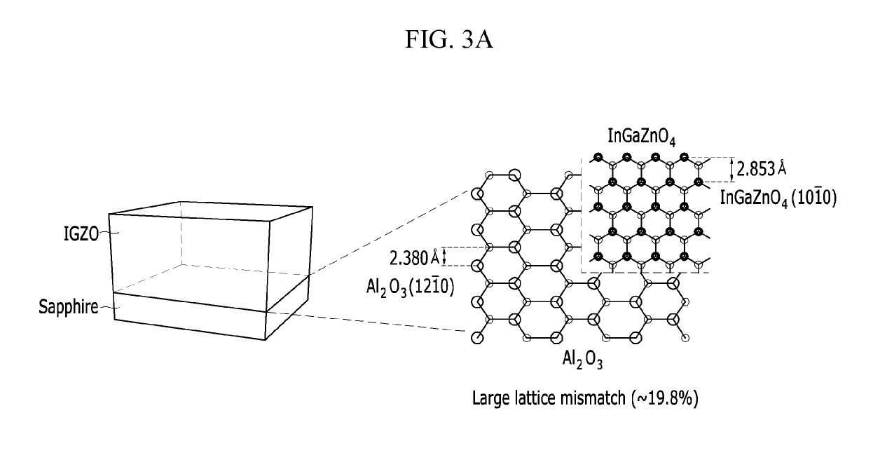

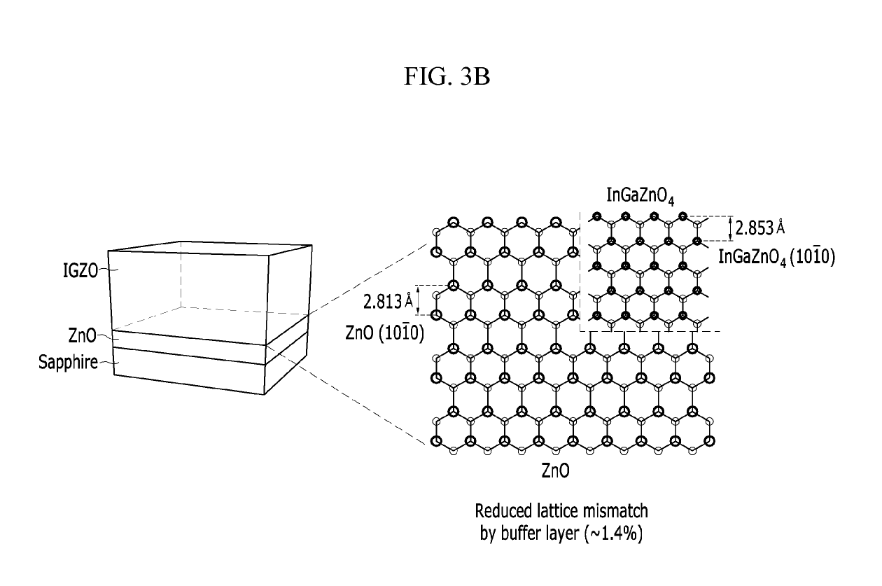

In some embodiments, a lattice mismatch between the seed layer 145 and semiconductor layer 154 is equal to or less than approximately 1.4%. The lattice mismatch between the seed layer 145 and semiconductor layer 154 will be described below with reference to FIG. 3B.

FIG. 3A is a diagram illustrating the extent of a lattice mismatch between an oxide semiconductor layer and a neighboring layer in a conventional thin film structure. FIG. 3B is a diagram illustrating the extent of a lattice mismatch between an oxide semiconductor layer and a neighboring layer according to an exemplary structure of the present inventive concept.

Referring to FIG. 3A, an IGZO (indium gallium zinc oxide) oxide semiconductor layer is formed directly on a sapphire substrate (the sapphire substrate including aluminum oxide). In the conventional thin film structure of FIG. 3A, a lattice mismatch of about 19.8% is measured at a boundary interface between the sapphire substrate and the oxide semiconductor layer.

Referring to FIG. 3B, a seed layer, which includes zinc oxide (ZnO), is formed between the sapphire substrate and the IGZO oxide semiconductor layer. In the exemplary structure of FIG. 3B, a lattice mismatch less than or equal to 1.4% is measured at a boundary interface between the seed layer and the oxide semiconductor layer.

Therefore, when a semiconductor layer 154 (e.g., an IGZO oxide semiconductor layer) is formed on a seed layer 145 (e.g., a ZnO layer) (for example, as shown in FIG. 2), the lattice mismatch between the layers can be significantly reduced. As a result of the reduced lattice mismatch, the growth rate of a crystal for forming a crystalline semiconductor layer is increased, and the crystal can be formed at a lower temperature, thereby increasing process efficiency.

Referring again to FIGS. 1 and 2, a source electrode 173 and drain electrode 175 are formed on portions of the semiconductor layer 154. The source electrode 173 and drain electrode 175 are formed opposite each other, with a channel region of the semiconductor layer 154 located between the source electrode 173 and drain electrode 175. The source electrode 173 is formed overlapping a portion of the gate electrode 124, and may be formed having an approximate U-shape (see, e.g., FIG. 1). Based on the location of the gate electrode 124, the drain electrode 175 may be formed in a shape as to face the source electrode 173. As shown in FIG. 1, the drain electrode 175 is formed extending upward from a center of the U-shaped source electrode 173. It should be readily appreciated that the structures of the source electrode 173 and drain electrode 175 are merely illustrative, and may be modified in various shapes.

A data wiring layer including the source electrode 173 and drain electrode 175 may be formed of metals or metal-based compounds including aluminum-based metals (such as aluminum or aluminum alloys), silver-based metals (such as silver or silver alloys), copper-based metals (such as copper or copper alloys such as copper manganese), molybdenum-based metals (such as molybdenum or molybdenum alloys), chromium, tantalum, or titanium. Alternatively, in some particular embodiments, the data wiring layer including the source electrode 173 and drain electrode 175 may be formed of a transparent conductive material such as ITO, IZO, AZO, or other similar transparent conductive materials. In some embodiments, the source electrode 173 and drain electrode 175 may have a multilayer structure including two or more conductive layers (not illustrated).

In some embodiments, the source electrode 173 and drain electrode 175 may each be formed continuously covering an upper surface of the gate insulating layer 140, lateral surfaces of the seed layer 145 and semiconductor layer 154, an upper surface of the semiconductor layer 154, and an edge portion of a barrier layer 160. (See, e.g., FIG. 2).

In some embodiments, the semiconductor layer 154 may have an exposed portion between the source electrode 173 and drain electrode 175 (that is not covered by the source electrode 173 and drain electrode 175). In those embodiments, a barrier layer 160 may be formed to cover the exposed portion of the semiconductor layer 154. (See, e.g., FIG. 2). The barrier layer 160 may be formed in an island shape, and may be formed of a metal oxide that easily combines with a gas (e.g., hydrogen) or gaseous radicals. For example, the barrier layer 160 may include oxides such as barium oxide, gallium oxide, lithium oxide, magnesium oxide, beryllium oxide, calcium oxide, strontium oxide, yttrium oxide, titanium oxide, vanadium oxide, zirconium oxide, indium oxide, lanthanum oxide, tantalum oxide, bismuth oxide, aluminum oxide, or other materials that can easily combine with a gas (such as hydrogen). The barrier layer 160 can protect the channel region of the semiconductor layer 154 from hydrogen and other gases (or gaseous radicals) that may be produced during subsequent semiconductor processing.

A single gate electrode 124, a single source electrode 173, and a single drain electrode 175 collectively form a single thin film transistor (TFT) together with the semiconductor layer 154, with a channel (or channel region) of the thin film transistor being formed between the source electrode 173 and drain electrode 175.

As shown in FIG. 2, a passivation layer 180 is formed on the source electrode 173, drain electrode 175, and barrier layer 160. The passivation layer 180 may be formed of, for example, an inorganic insulating material (such as silicon nitride or silicon oxide), an organic insulating material, an insulating material having low permittivity, or other types of insulating materials.

As shown in FIG. 2, a contact hole 185 is formed in the passivation layer 180 to expose a portion of the drain electrode 175. A pixel electrode 191 is formed on portions of the passivation layer 180 extending into the contact hole 185, such that the pixel electrode 191 is physically and electrically connected to the drain electrode 175 through the contact hole 185. The pixel electrode 191 may be formed of a transparent conductor such as ITO, IZO, or other similar transparent conductive materials.

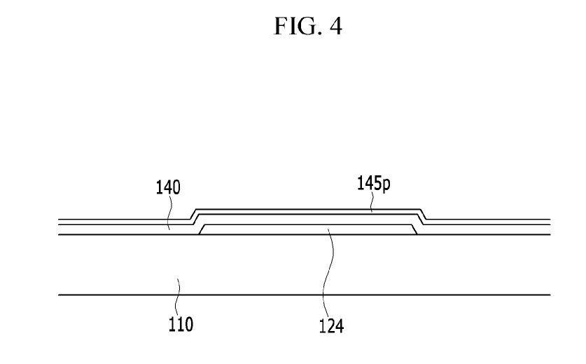

Next, an exemplary method of manufacturing the thin film transistor array panel of FIGS. 1 and 2 will be described with reference to FIGS. 4 to 15.

FIGS. 4 to 15 are cross-sectional views illustrating an exemplary method of manufacturing the thin film transistor array panel according to the present inventive concept. Specifically, FIGS. 4 to 15 illustrate cross-sectional views taken along line II-II of FIG. 1 at different steps during the fabrication of the thin film transistor array panel.

Referring to FIG. 4, a gate electrode 124 is formed on a substrate 110. A gate insulating layer 140 is formed on the gate electrode 124 (covering the gate electrode 124), and a seed material layer 145p is formed on the gate insulating layer 140.

The gate insulating layer 140 and seed material layer 145p may be formed sequentially formed using a same piece of equipment, which improves process efficiency and reduces the occurrence of foreign particles between the interfaces. The gate insulating layer 140 and seed material layer 145p may be formed using, for example, a physical vapor deposition method. A heat treatment may be performed on the seed material layer 145p. For example, the heat treatment may be carried out at a temperature of more than or equal to 100° C., and less than or equal to 500° C.

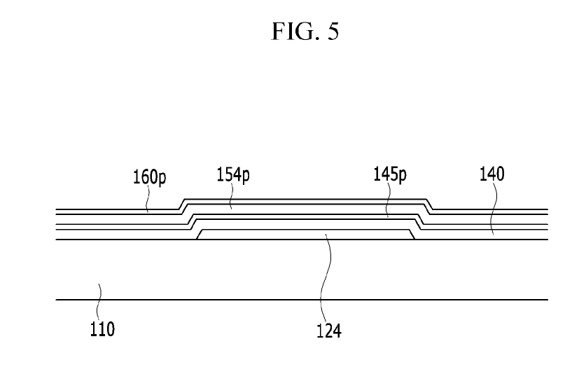

Referring to FIG. 5, a semiconductor material layer 154p is formed on the seed material layer 145p. A heat treatment can also be performed on the semiconductor material layer 154p. The conditions of the heat treatment of the semiconductor material layer 154p are similar to those of the heat treatment of the seed material layer 145p. However, in some embodiments, the heat treatment of the semiconductor material layer 154p may be performed at higher temperatures than the heat treatment of the seed material layer 145p. The heat treatment of the semiconductor material layer 154p increases the stability of the semiconductor layer of the thin film transistor, and produces a semiconductor layer having a C-axis aligned crystal (CAAC) structure.

Next, a barrier material layer 160p is formed on the semiconductor material layer 154p. The barrier material layer 160p may be formed of, for example, aluminum oxide.

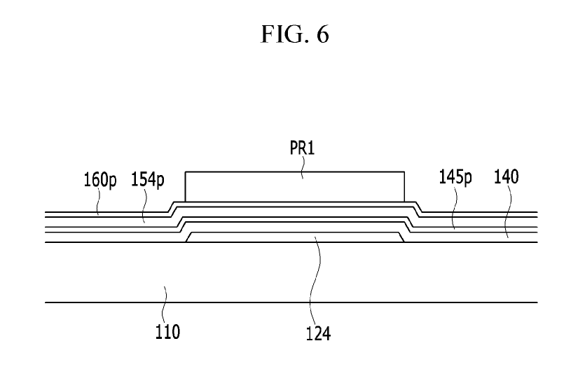

Referring to FIG. 6, a first photosensitive film pattern PR1 is formed on the barrier material layer 160p.

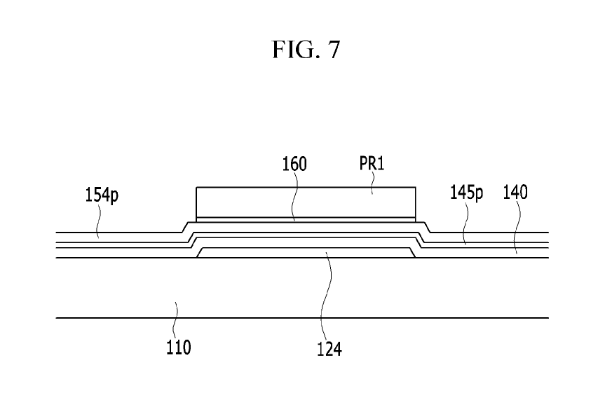

Referring to FIG. 7, a barrier layer 160 is formed by etching the barrier material layer 160p using the first photosensitive film pattern PR1 as an etch mask. The barrier layer 160 can protect the channel region of the semiconductor layer 154 from gases (such as hydrogen) or gaseous radicals that may be generated during subsequent semiconductor processing. The barrier layer 160 may be formed using, for example, a dry etching method.

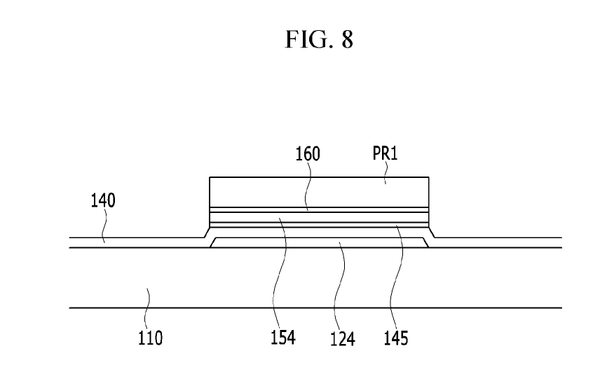

Referring to FIG. 8, the semiconductor material layer 154p and seed material layer 145p are sequentially etched using the first photosensitive film pattern PR1 as an etch mask.

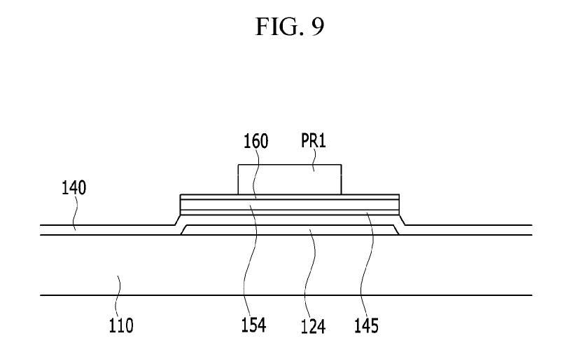

Referring to FIG. 9, the first photosensitive film pattern PR1 undergoes an ashing process (e.g., oxygen ashing), which reduces the width and height of the first photosensitive film pattern PR1. As shown in FIG. 9, edge portions of the barrier layer 160 are exposed after the ashing process.

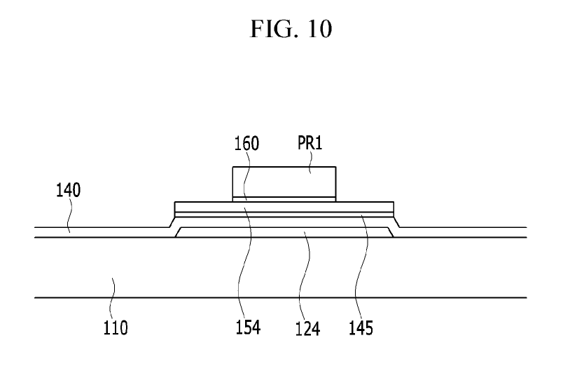

Referring to FIG. 10, the exposed edge portions of the barrier layer 160 are etched using the (ashed) first photosensitive film pattern PR1 (from FIG. 9) as an etch mask, so as to expose edge portions of the semiconductor layer 154.

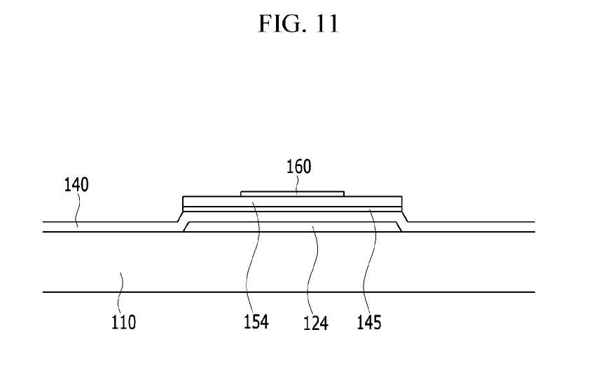

Referring to FIG. 11, the (ashed) first photosensitive film pattern PR1 is removed.

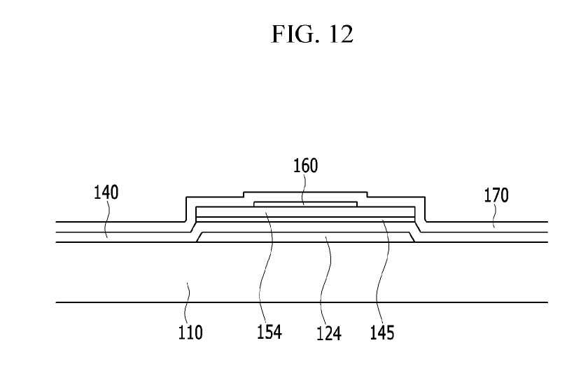

Referring to FIG. 12, a data wiring material layer 170 is formed on the exposed portions of the gate insulating layer 140, semiconductor layer 154, and barrier layer 160.

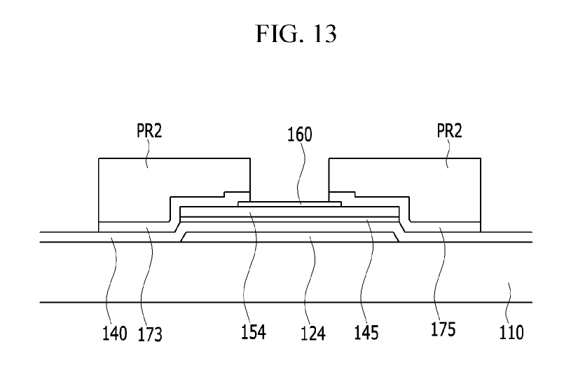

Referring to FIG. 13, a second photosensitive film pattern PR2 is formed on the data wiring material layer 170. The second photosensitive film pattern PR2 is formed so as to expose a center portion of the data wiring material layer 170 overlapping with the barrier layer 160. Next, the data wiring material layer 170 is etched using the second photosensitive film pattern PR2 as an etch mask to form the source electrode 173 and drain electrode 175. As shown in FIG. 13, the source electrode 173 and drain electrode 175 are formed opposite each other, with the channel region of the semiconductor layer 154 located between the source electrode 173 and drain electrode 175.

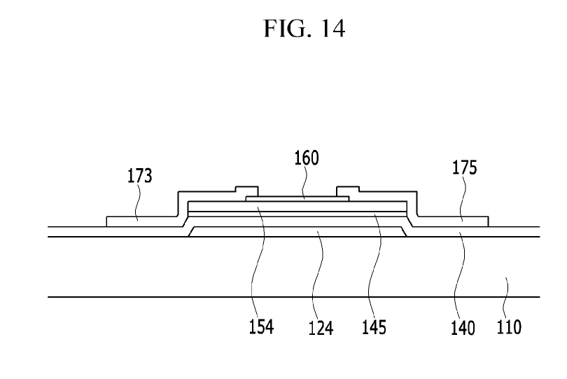

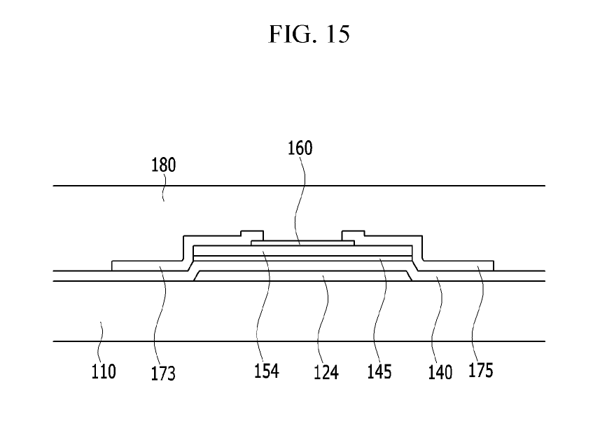

Referring to FIG. 14, the second photosensitive film pattern PR2 is removed. Referring to FIG. 15, a passivation layer 180 is formed over the structure of FIG. 14 covering the exposed portions of the gate insulating layer 140, source electrode 173, drain electrode 175, and barrier layer 160.

Next, a contact hole 185 is formed in the passivation layer 180. A pixel electrode 191 is then formed on portions of the passivation layer 180 extending into the contact hole 185, producing the thin film transistor array panel illustrated in FIG. 2.

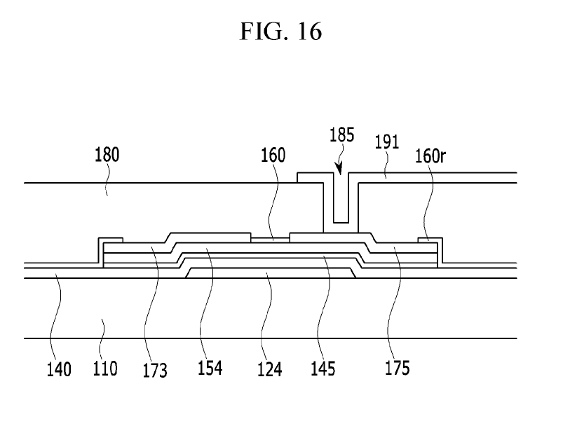

FIG. 16 is a cross-sectional view illustrating a thin film transistor array panel according to another embodiment of the present inventive concept.

Most of the elements in FIG. 16 are the same as the elements in FIG. 2. However, FIG. 16 includes some features that are different from those in FIG. 2.

For example, in FIG. 16, a data wiring layer including a source electrode 173 and drain electrode 175 has substantially the same edge boundary in a plane pattern as a seed layer 145 and semiconductor layer 154, except at a portion where a barrier layer 160 is positioned. Having the above structural characteristic (i.e., same edge boundary) allows the seed layer 145, semiconductor layer 154, source electrode 173, and drain electrode 175 to be patterned using a same mask.

FIG. 16 also shows the barrier layer 160 being formed between the source electrode 173 and drain electrode 175. A width of the barrier layer 160 may be equal to a width between the source electrode 173 and drain electrode 175. In some embodiments, the width of the barrier layer 160 may be less than the width between the source electrode 173 and drain electrode 175.

Additionally, FIG. 16 shows barrier material layer residual portion 160r formed on the exposed portions of the gate insulating layer 140, source electrode 173, and drain electrode 175 (as well as side/lateral portions of the seed layer 145 and semiconductor layer 154).

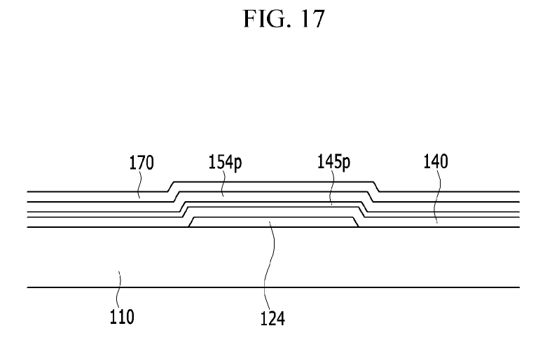

Hereinafter, an exemplary method of manufacturing the thin film transistor array panel in FIG. 16 will be described with reference to FIGS. 17 to 23.

FIGS. 17 to 23 are cross-sectional views illustrating an exemplary method of manufacturing the thin film transistor array panel of FIG. 16. Specifically, FIGS. 17 to 23 illustrate cross-sectional views taken along line II-II of FIG. 1 at different steps during the fabrication of the thin film transistor array panel.

Referring to FIG. 17, a gate electrode 124 is formed on a substrate 110, and a gate insulating layer 140 is formed on the gate electrode 124. Next, a seed material layer 145p, semiconductor material layer 154p, and data wiring material layer 170 are sequentially deposited on the gate insulating layer 140. A heat treatment of the semiconductor material layer 154p may be performed prior to depositing the data wiring material layer 170.

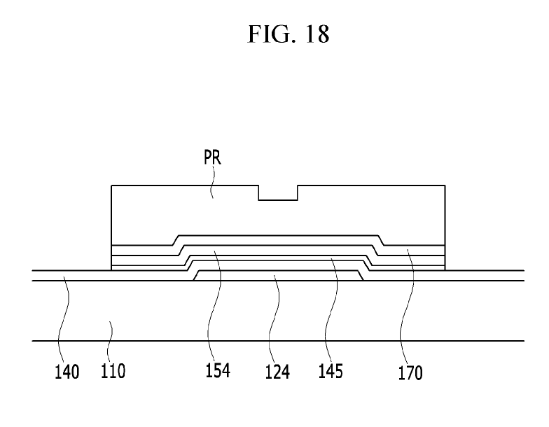

Referring to FIG. 18, a photosensitive film pattern PR is formed on a portion of the data wiring material layer 170. As shown in FIG. 18, a portion of the photosensitive film pattern PR (above a target channel region) may be formed having a decreased thickness relative to other portions of the photosensitive film pattern PR. The data wiring material layer 170, semiconductor material layer 154p, and seed material layer 145p are then etched using the photosensitive film pattern PR as an etch mask. A seed layer 145 is formed by the etching of the seed material layer 145p.

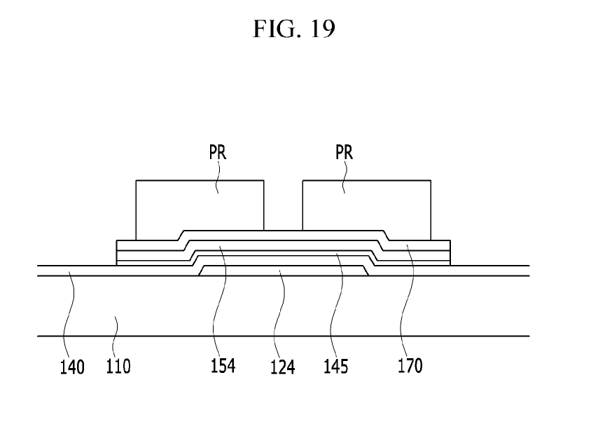

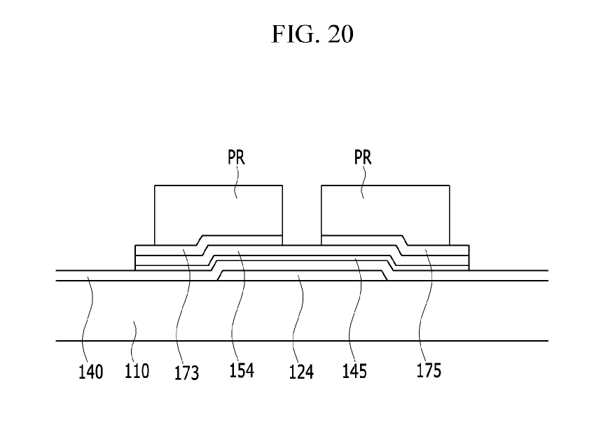

Referring to FIG. 19, the photosensitive film pattern PR is etched back to form a cavity, and the thinner portion of the photosensitive film pattern PR (above the target channel portion) is removed to expose the data wiring material layer 170. Referring to FIG. 20, the exposed data wiring material layer 170 is then etched to form a source electrode 173 and drain electrode 175, and to expose the channel region of the semiconductor layer 154.

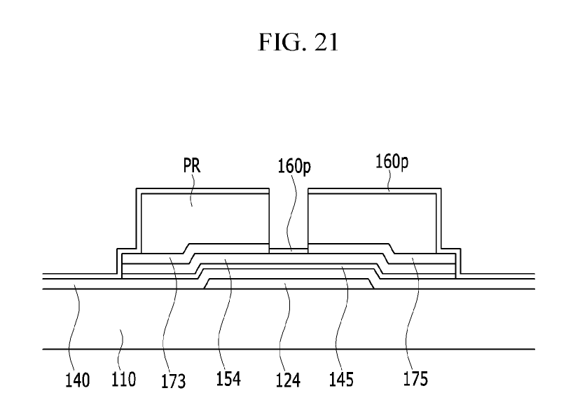

Referring to FIG. 21, a barrier material layer 160p is formed on the exposed portions of the gate insulating layer 140, source electrode 173, drain electrode 175, and semiconductor layer 154, except on the inner sidewalls of the cavity. The barrier material layer 160p may be formed of, for example, aluminum oxide. In some embodiments, a process condition for forming the barrier material layer 160p may be adjusted, such that the barrier material layer 160p does not form one single continuous layer. For example, a first portion of the barrier material layer 160p may be formed on the exposed portion of the semiconductor layer 154 between the source electrode 173 and drain electrode 175, and a second portion of the barrier material layer 160p may be formed on the photosensitive film pattern PR.

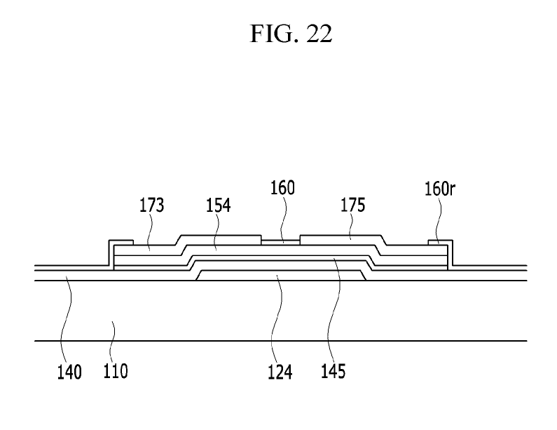

Referring to FIG. 22, the photosensitive film pattern PR is removed, for example, using a “lift-off” method. The “lift-off” results in a barrier layer 160 located on the semiconductor layer 154 between the source electrode 173 and drain electrode 175. The “lift-off” also results in a barrier material layer residual portion 160r located on the parts of the gate insulating layer 140, source electrode 173, and drain electrode 175 that were not covered by the photosensitive film pattern PR. In some embodiments, the barrier material layer residual portion 160r may be removed by an additional cleaning process.

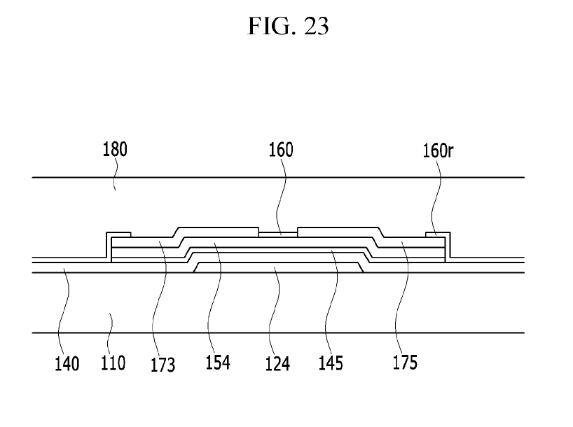

Referring to FIG. 23, a passivation layer 180 is formed over the structure of FIG. 22 to cover the barrier material layer residual portion 160r, source electrode 173, drain electrode 175, and barrier layer 160.

Next, a contact hole 185 is formed in the passivation layer 180, and a pixel electrode 191 is formed on portions of the passivation layer 180 extending into the contact hole 185, so as to produce the thin film transistor array panel illustrated in FIG. 16.

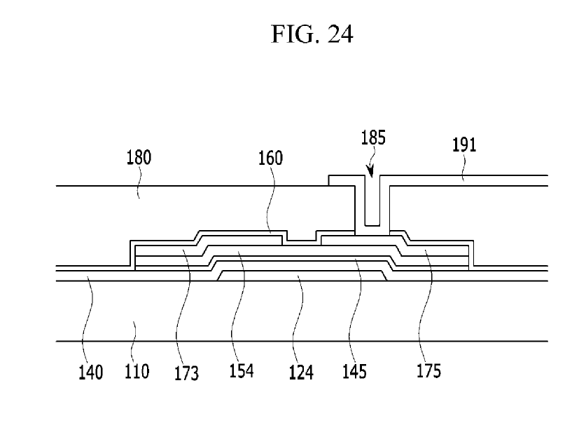

FIG. 24 is a cross-sectional view illustrating a thin film transistor array panel according to a further embodiment of the present inventive concept.

Most of the elements in FIG. 24 are the same as the elements in FIG. 16. However, FIG. 24 includes some features that are different from those in FIG. 16.

For example, in FIG. 24, the barrier layer 160 is formed on the exposed portions of the source electrode 173, drain electrode 175, and gate insulating layer 140, and on the portion of the semiconductor layer 154 that is not covered by the source electrode 173 and drain electrode 175. In contrast, FIG. 16 shows the barrier layer 160 formed only on the exposed portion of the semiconductor layer 154 between the source electrode 173 and drain electrode 175.

Next, an exemplary method of manufacturing the thin film transistor array panel in FIG. 24 will be described. This method includes the process steps described with reference to FIGS. 17 to 20, and thus reference to the previously-described process steps shall be omitted. The differences in this method occur after the step described in FIG. 20, as described below.

In some embodiments, after the etching process (in FIG. 20) is performed using the photosensitive film pattern PR as an etch mask, the photosensitive film pattern PR is removed. Next, a barrier layer 160 is formed on the exposed portions of the gate insulating layer 140, source electrode 173, drain electrode 175, and semiconductor layer 154. A passivation layer 180 is then formed over the structure. Next, a contact hole 185 is formed in the passivation layer 180, and a pixel electrode 191 is formed on portions of the passivation layer 180 extending into the contact hole 185, so as to produce the thin film transistor array panel shown in FIG. 24.

While this inventive concept has been described in connection with what is presently considered to be practical exemplary embodiments, it is to be understood that the inventive concept is not limited to the disclosed embodiments, but, on the contrary, is intended to cover various modifications and equivalent arrangements included within the spirit and scope of the appended claims.

What is claimed is:

1. A thin film transistor array panel, comprising:
a substrate;
a seed layer positioned on the substrate; and
a semiconductor layer positioned on the seed layer,
wherein a lattice mismatch between the seed layer and the semiconductor layer is equal to or less than 1.4%.

2. The thin film transistor array panel of claim 1, wherein:
the seed layer includes an amorphous oxide semiconductor, and the semiconductor layer includes a crystalline oxide semiconductor.

3. The thin film transistor array panel of claim 2, wherein:
the seed layer includes an oxide semiconductor including at least one of indium, gallium, and zinc.

4. The thin film transistor array panel of claim 3, wherein:
the semiconductor layer includes an oxide semiconductor including at least one of indium, gallium, zinc, and tin.

5. The thin film transistor array panel of claim 4, wherein:
the oxide semiconductor is formed having a C-axis aligned crystal (CAAC) structure.

6. The thin film transistor array panel of claim 1, further comprising:
a gate electrode positioned on the substrate;
a gate insulating layer positioned on the substrate to cover the gate electrode; and
a source electrode and a drain electrode positioned on the semiconductor layer,
wherein the seed layer and the semiconductor layer are sequentially positioned on the gate insulating layer.

7. The thin film transistor array panel of claim 6, further comprising
a barrier layer positioned on the semiconductor layer,
wherein an edge portion of the barrier layer is covered by the source electrode and the drain electrode.

8. The thin film transistor array panel of claim 7, wherein:
the barrier layer is formed having an island shape.

9. The thin film transistor array panel of claim 8, wherein:
the barrier layer includes aluminum oxide.

10. A method of manufacturing a thin film transistor array panel, comprising:
forming a gate electrode on a substrate;
forming a gate insulating layer on the substrate to cover the gate electrode;
forming a seed material layer on the gate insulating layer;
forming a semiconductor material layer on the seed material layer;
forming a first photosensitive film pattern on the semiconductor material layer;
forming a semiconductor layer and a seed layer by patterning the semiconductor material layer and the seed material layer using the first photosensitive film pattern as a first etch mask;
removing the first photosensitive film pattern;
forming a data wiring material layer on the gate insulating layer to cover the semiconductor layer;
forming a second photosensitive film pattern on the data wiring material layer; and
forming a source electrode and a drain electrode facing the source electrode, by patterning the data wiring material layer using the second photosensitive film pattern as a second etch mask.

11. The method of claim 10, wherein:
a lattice mismatch between the seed layer and the semiconductor layer is equal to or less than 1.4%.

12. The method of claim 11, wherein:
the seed layer is formed of an amorphous oxide semiconductor, and the semiconductor layer is formed of a crystalline oxide semiconductor.

13. The method of claim 12, wherein:
the seed layer is formed of an oxide semiconductor including at least one of indium, gallium, and zinc, and the semiconductor layer is formed of an oxide semiconductor including at least one of indium, gallium, zinc, and tin.

14. The method of claim 13, wherein:
the oxide semiconductor is formed having a C-axis aligned crystal (CAAC) structure.

15. The method of claim 10, further comprising:
forming a barrier material layer on the semiconductor material layer before forming the first photosensitive film pattern,
wherein the barrier material layer is formed of aluminum oxide, and
forming a barrier layer by patterning the barrier material layer using the first etch mask.

16. The method of claim 15, further comprising:
exposing an edge portion of the barrier layer by ash processing the first photosensitive film pattern after forming the semiconductor layer and the seed layer; and
etching the barrier layer using the ash-processed first photosensitive film pattern as a third etch mask,
wherein the data wiring material layer is formed covering an edge portion of the semiconductor layer, the edge portion being exposed by etching the barrier layer.

17. The method of claim 10, further comprising:
forming a passivation layer on the source electrode and the drain electrode; and
forming a pixel electrode on the passivation layer,
wherein the pixel electrode and the drain electrode are connected through a contact hole formed at the passivation layer.

18. The method of claim 10, further comprising:
performing a heat treatment of the seed material layer.
